(19) United States
(12) Patent Application Publication
(10) Pub. No.: US 2019/0296683 A1
(43) Pub. Date: Sep. 26, 2019

(54) ADHESIVE MOUNTING OF PHOTOVOLTAIC MODULES ON ROOFS

(71) Applicant: Fraunhofer USA, Inc., Plymouth, MI (US)

(72) Inventors: Christian Honeker, Cambridge, MA (US); Christian Hoepfner, Cambridge, MA (US); Hans C. Henning, Gloucester, MA (US)

(73) Assignee: Fraunhofer USA, Inc., Plymouth, MI (US)

(21) Appl. No.: 15/927,197

(22) Filed: Mar. 21, 2018

(51) Int. Cl. H02S 20/23; H01L 31/043; H01L 31/048

(52) U.S. Cl. CPC H02S 20/23; H01L 31/048; H01L 31/043

(57) ABSTRACT

Described herein are embodiments of an approach to attaching one or more photovoltaic (PV) modules to a roof of a building. More particularly, described herein are embodiments of an approach to attaching glass-glass PV modules using an adhesive. Such an adhesive may be applied to contact points between the roof and a support frame that holds the glass-glass PV module(s) in place and that may be mechanically coupled to the glass-glass PV module(s). Use of the adhesive in this way may be particularly advantageous when the roof is sloped, including when the roof has a steep slope, which may include roofs having a rise-to-run ratio greater than 4:12, greater than 6:12, or greater than 8:12. The adhesive may, in some embodiments, aid in reducing, minimizing, or eliminating the use of mechanical anchor points that may be needed to support the glass-glass PV module(s) on the roof.

### BACKGROUND

Photovoltaic (PV) modules, also sometimes known as solar panels, can be used to output electric power when irradiated, such as when irradiated with sunlight. Photovoltaic modules may be installed (e.g., on a roof) in an array of modules, for example a 2×4 array or a 1×5 array.

There are multiple types of PV modules.

Many PV modules are constructed of a stack of layers beginning with a sun-facing glass frontsheet (which may be made of a low-iron glass, which may also be known as “PV glass” or more simply “glass” herein), a soft encapsulant, an active layer containing a photovoltaic circuit (e.g., crystalline silicon cells linked by conductive interconnects), another soft encapsulant, and a final polymeric film. This stack of materials is supported by an aluminum frame that prevents excessive deflection (e.g., bending) and provides a mounting interface. Such modules may be supported on a roof or other surface by rails and/or mounting clamps located at the frame at manufacturer-specified positions to minimize deflection under load (such loads occur due to snow, wind, seismic activity as well as the weight of the module itself). Conventional framed modules containing crystalline silicon cells designed for rooftops typically weigh 18-19 kg and have dimensions of 1 m×1.6 m.

A second type of PV module is known as a “glass-glass” design and consists of a sun-facing glass frontsheet, a soft encapsulant, the photovoltaic circuit, a second soft encapsulant, and a final glass layer. This “glass-glass” design may have a frame or may be frameless, and often has improved durability as compared with the framed design of the first type of PV module described above. Glass-glass module dimensions are similar to the framed module of the first type, but their weight is often higher due to the additional glass layer. Depending on the thickness of the front and back glass, glass-glass module weights range from 23 to 30 kg. Mounting of frameless glass-glass modules is often more challenging than mounting framed modules of the first type, as improper clamping of glassless frameless modules risks cracking the glass.

A third type of PV modules are lightweight modules that do not include any glass layer nor any frame. Such glassless, frameless designs include PV modules distributed by Lumeta, Inc., (“Lumeta Solar”) of Irvine, Calif.

Herein, PV modules of the first type, having a single glass layer (the frontsheet) may be referred to as “glass” PV modules, PV modules of the second type having two glass layers may be referred to as “glass-glass” PV modules, and PV modules of the third type may be referred to as “glassless” modules.

### SUMMARY

In one embodiment, there is provided an apparatus for attaching a glass-glass photovoltaic module to a sloped roof, the apparatus comprising a support frame, the support frame comprising a mechanical interface to hold at least one glass-glass photovoltaic module in place and at least one surface, disposed opposite the mechanical interface, coated with an adhesive to couple the apparatus to the sloped roof.

In another embodiment, there is provided a method for installing at least one glass-glass photovoltaic module to a sloped roof. The method comprises marking at least one location on the sloped roof at which to install the at least one glass-glass photovoltaic module, removing a liner protecting an adhesive coated on at least one support frame, the at least one support frame being designed to hold the at least one glass-glass photovoltaic module in place, placing the at least one support frame on the sloped roof at the at least one location, pressing the at least one support frame to achieve sufficient adhesive strength, and attaching the at least one glass-glass photovoltaic module to the at least one support frame.

In a further embodiment, there is provided a method for manufacturing an apparatus for attaching a glass-glass photovoltaic module to a sloped roof. The method comprises making a support frame, making a foam pad, coating one side of the foam pad with an adhesive, attaching a side of the foam pad opposite the side coated with the adhesive to the support frame, and distributing the support frame with the attached foam pad from a factory.

### BRIEF DESCRIPTION OF DRAWINGS

In the drawings:

FIG. 1 is a sketch of an illustrative system in which a glass-glass photovoltaic module may be installed on a steep-slope roof.

FIG. 2A is a sketch of a cross-sectional view of an embodiment of a system for attaching a glass-glass PV module to a steep-slope roof.

FIGS. 2B-2C illustrate examples of a support frame.

FIGS. 3A-3B illustrate examples of mechanical anchor points.

FIGS. 4A-4B illustrate examples of clamps that may be used to attach a glass or glass-glass PV module to a support frame.

FIG. 5 is a sketch of a closer cross-sectional view of an embodiment of the apparatus, specifically a view of a support frame attached to a steep-slope roof.

FIGS. 6A-6D show an embodiment in which a glass or glass-glass PV module may be attached to a steep-slop roof using rails attached to adhesive pads.

FIGS. 7A-7B show an embodiment for a glass-glass PV module in which rails are attached between adhesive pads.

FIGS. 8A-8B show an embodiment in which a support frame includes hinged adhesive pads to attach to a steep-slope roof.

FIGS. 9A-D show an embodiment in which a PV module may be attached to a roof using a “triad” design.

FIG. 10 is a flowchart of a process for installing a support system for a glass or glass-glass PV module according to some embodiments.

FIG. 11 is a flowchart of a process for manufacturing some embodiments.

### DETAILED DESCRIPTION

Described herein are embodiments of an approach to attaching one or more (including an array of) photovoltaic (PV) modules to a steep-slope roof of a building, such as a residential or commercial building. More particularly, described herein are embodiments of an approach to attaching PV modules using an adhesive. Such an adhesive may be applied to contact points between the roof and a support frame that holds the PV module(s) in place and that may be mechanically coupled to the PV module(s). In some embodiments, the PV modules may be glass-glass PV modules. Use of the adhesive in this way may be particularly advantageous to aid in reducing, minimizing, or eliminating the use of penetrating mechanical anchor points to support the glass-glass PV module(s) on the roof. The adhesive may be used when the roof is sloped, including when the roof has a steep slope, which may include roofs having a rise-to-run ratio greater than 4:12, greater than 6:12, or greater than 8:12.

Typically, glass and glass-glass PV modules are attached to sloped roofs, particularly steeply-sloped roofs, using mechanical anchor points. Such anchor points may penetrate the roof, such as when the anchor points are bolts that pass through the support frame and the weather-proofing layer of the roof, to mechanically couple the support frame to the roof. The inventors have recognized and appreciated that mechanical anchor points may be disadvantageous in some cases. Where such anchor points penetrate the roof, they risk introducing leaks to the roof. As such, homeowners maybe concerned about the effect of the mounting system on the roof's water-tightness over the expected lifetime of the roof. The inventors further recognize that the time and skill necessary to install the anchor points for modules may undesirably increase the cost and complexity of installation.

Adhesives have been used to attach lightweight, glassless frameless PV modules to roofs, to avoid the need for penetrating anchor points with such glassless frameless modules. In such a case, a portion of the rear surface is covered with an adhesive. By mounting the junction box on the module's front side, the lightweight glassless module can be adhered directly to the roof without the need of a support frame.

This “direct adhesion” approach is not viable for installing frameless glass-glass modules nor framed glass modules. The rear surface of these modules may not be flat and may instead include components such as an electrical junction box. For framed glass modules, the frame may not provide sufficient area for the adhesive to effectively attach the module to the roof. Thus, a support frame may be necessary to provide space to accommodate the components as well as to provide sufficient area for effective adhesive bonding. In addition, the support frame may provide increased ventilation under the module to reduce heat build-up of the module. It is known that as the gap between the module and the roof decreases, the module temperature increases, which may reduce performance of the module. Thus, direct adhesion of glass-glass modules is not viable for two reasons. First, without adequate ventilation, the glass-glass PV modules may increase in temperature, which is known to cause a corresponding drop in performance, or could even risk damaging the glass-glass PV module if the temperature rises significantly. Second, the rear surface of glass-glass modules is not flat, and may instead include components such as an electrical junction box. As such, the rear surface cannot be simply adhered to a roof by coating the rear surface in adhesive, in the same manner that the flat glassless frameless modules are.

For these reasons, as discussed above, glass and glass-glass PV modules are conventionally attached to roofs via a support frame connected to the roof at mechanically-attached mounts. Such a conventional support frame would be unsuitable for an adhesive mounting approach. The mechanically-attached mounts may concentrate the stress of the loads experienced by the support frame (e.g., from snow, wind, seismic loads, as well as the module weight) at a handful of contact points with the roof, where the mechanical anchor points are installed. The few contact points securing the support frame to the roof may have insufficient cumulative surface area for the adhesive to manage the stress of these loads. If the forces exceed the adhesive strength, the modules could become separated from the roof or otherwise become damaged, or could damage other property, people, etc. in a fall to the ground.

The challenge of attaching glass and glass-glass PV modules and frames to a roof may be even more pronounced for sloped roofs having a rise-to-run ratio greater than 2:12, and in particular for sloped roofs that have a steep slope, such as a slope with a rise-to-run ratio greater than 4:12, greater than 6:12, or greater than 8:12. For such a sloped roof, as compared to a flat roof, the weight of the glass-glass PV modules and the support frame may increase shear stress on the contact points between the frame and roof. Such an increased shear stress presents further challenges to use of an adhesive, and encourages use of mechanical anchor points.

A further challenge of using adhesives with glass-glass PV modules is the likelihood, if an adhesive were to be used, for the glass-glass PV modules and support frame to suffer from “creep.” “Creep” would occur when the glass-glass PV modules and the frame shift from their initial positions over time, as the modules and frame slowly slide down the roof in spite of the adhesive. Creep can occur, for example, due to the heavy load of the glass-glass PV modules and support frame, a steepness of the incline of the roof, because of high temperatures the adhesive may be exposed to on roofs, and/or other factors. Over time, such creep may apply stresses to other components of a PV array, such as physical/wired connections between electrical components, as the PV modules move from original positions and begin stretching or pulling against the physical/wired connections or otherwise moving away from other components of fixed positions, which may risk damaging such other electrical components of the array. Over time, creep may also pose a risk of the glass-glass PV modules becoming separated from the roof.

An additional challenge is the uneven nature of the surface of a shingled roof. There are three length-scales of roof unevenness that can affect adhesive mounting. The roof can sag or bow at the length-scale of a module. Since modules are flat and rigid, a support frame can accommodate roof unevenness while providing a flat surface for module attachment. A shingled roof also has a natural unevenness at the length-scale of the shingle due to the overlapping of the individual shingles, resulting in a stepped surface of the roof. Finally, the shingle surface itself may be uneven due to granules embedded into the shingle. The unevenness at these length-scales pose a challenge for the effectiveness of adhesive mounting, as the unevenness may prevent or adversely affect binding of the adhesive to the roof.

The inventors have thus recognized and appreciated that there are a number of significant and substantial challenges to use of adhesives to attach glass-glass PV modules to roofs with steep slopes. As a result of these challenges, adhesives have heretofore not been used in the art for attaching PV modules with glass layers (e.g., glass PV modules and glass-glass PV modules) to roofs, and in particular have not been used for attaching glass-glass PV modules to roofs with steep slopes.

Described herein are embodiments of an approach for attaching one or more glass and/or glass-glass PV modules to a roof using an adhesive. Some such embodiments include techniques for attaching the PV module(s) to a roof with a steep slope. In some embodiments, an apparatus for attaching PV modules to a roof may include a support frame that is coupled to the steep roof with an adhesive. The support frame may also, in some cases, include a mechanical interface designed to hold the PV module(s) in place. In embodiments in which the PV modules are glass-glass PV modules, the glass-glass PV modules may have a frame (a module frame, which may be in addition to any support frame) or may be frameless.

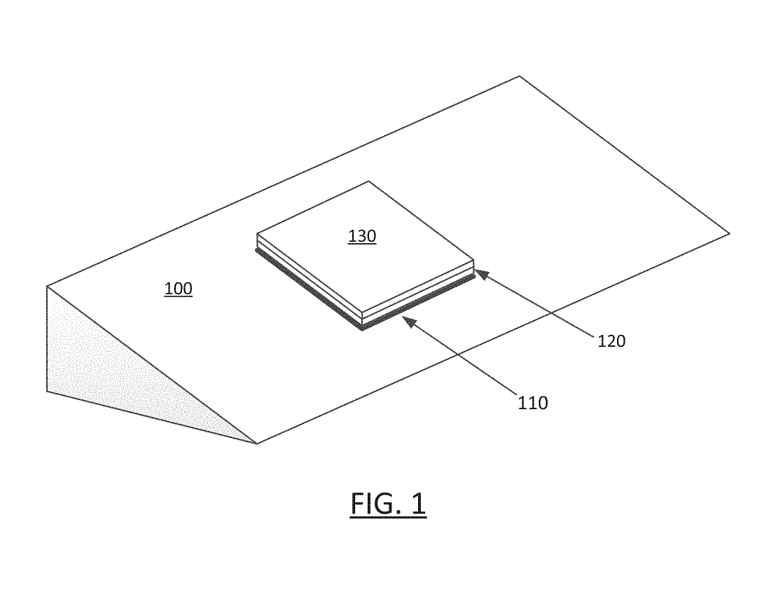

FIG. 1 shows an illustrative system in which a PV module 130 may be installed on a roof 100. PV module 130 includes at least one glass layer. Accordingly, PV module 130 may be a glass PV module or a glass-glass PV module. In the example of FIG. 1, the PV module 130 may advantageously be a glass-glass PV module, and is accordingly referenced as a glass-glass module below. It should be appreciated, however, that embodiments are not so limited.

Glass-glass PV module 130 may be attached to the roof via a support frame 120. The glass-glass PV module 130 may be coupled to the support frame 120 such that it may be decoupled from support frame 120 at a later time. In some embodiments, the support frame 120 may include a mechanical interface to hold the glass-glass PV module 130 in place, which may include one or more clamps. In another embodiment, the mechanical interface may have a skeletal, scaffold-type shape. Embodiments are not limited to a specific type of mechanical interface to couple the glass-glass PV module 130 to the support frame 120.

The support frame 120 may be designed to hold the glass-glass PV module 130 at a distance from the roof 100. This may provide the glass-glass PV module 130 with adequate ventilation to reduce heat build-up, and thus avoid degradation of module performance. In some embodiments, the support frame 120 may hold the glass-glass PV module 130 at a distance from the roof 100 between 1 inch and 7.5 inches.

In some cases, the support frame 120 may be a metal support frame. In other embodiments, the support frame 120 may be made out of plastic, or a combination of materials. The support frame 120 may also be an overmolded metal support frame, in which the metal support frame is surrounded by a layer of nonmetallic material. In some embodiments, the nonmetallic material may be a plastic. The overmolded metal support frame may be designed such that the metal is surrounded by plastic in order to electrically isolate the metal from the PV module. It should be appreciated that embodiments are not limited to using any particular type of material or combination of materials for the support frame, and those skilled in the art may select the material(s) to provide the functionality of the support frame 120 described herein.

The support frame 120, mechanically coupled to glass-glass PV module 130, may be attached to a roof 100 with an adhesive 110. In some embodiments, adhesive 110 may be chosen for its strength and durability over an expected life of a glass-glass PV module 130 (typically 25 years). Loads experienced by the adhesive 110 may include tensile loads (perpendicular to the surface of the roof) and shear loads (parallel to the surface of the roof). Tensile loads may include loads arising from negative pressure caused by wind passing over the roof 100 (wind uplift). Shear loads may include loads arising from the weight of the support frame 120 and the glass-glass PV module 130, as well as snow loads and seismic loads. In some jurisdictions, installation standards for PV modules require that the mounting product meet certain metrics in certain test geometries. In such jurisdictions, it may be important for the adhesive 110 to meet those standards. The adhesive 110 may also be chosen to have sufficient green strength to hold the support frame 120 to the roof 100 during preliminary bonding of the adhesive 110 to the roof 100, before the adhesive 110 has fully cured and developed ultimate bond properties. In some embodiments, the adhesive 110 may be a temperature-resistant adhesive.

In some embodiments, it may be desirable for the adhesive to have uplift resistance of at least 7.5 pounds per square foot (psf) for 30 minutes, in accordance with UL standard 2703 Edition 1 Section 21. In some embodiments, it may be desirable for the adhesive to have an uplift resistance that will pass uplift testing performed under ICC-ES standard AC365.

In some embodiments, the adhesive 110 may be a pressure-sensitive adhesive that, when pressure is applied, forms a bond to adhere the support frame 120 to the roof 100. As one specific example, HelioBond PVA 900 HM (Royal Adhesive and Sealants) may be used as the adhesive 110 in some embodiments. Further types of adhesive including pressure-sensitive adhesives appropriate for module mounting are described in U.S. Patent Pub. No. 2012/0198780, which is herein incorporated by reference. (Any terminology used in both this application and U.S. Patent Pub. No. 2012/0198780 should be construed to have a meaning most consistent with its usage in this application.)

It should be appreciated that embodiments are not limited to operating with any particular adhesive or type of adhesive. One skilled in the art will be able to select an appropriate adhesive to satisfy the conditions described above, for use in attaching support frame 120 (and the glass-glass PV module(s) 130 attached to the support frame 120) to the roof 100.

In some embodiments, as shown in FIG. 1, the roof 100 may be sloped, including steeply sloped. In such embodiments, the slope may cause a larger shear stress to be applied to the contact points of the support frame. As discussed above, in some cases, this may cause the support frame 120 and glass-glass PV module 130 to suffer from “creep,” shifting from their initial positions over time, as the support frame 120 and glass-glass PV module 130 may slowly slide down the roof in spite of the adhesive 110. The effect of such creep may be even more pronounced in the case where the roof 100 is steeply sloped. Steep-slope roofs are often shingled and uneven, such as in the case of asphalt-shingle roofs. Such roofs may increase the difficulty of effectively adhering the support frame 120 to the roof 100.

The support frame 120 may include enough contact points or contact surface area with the roof 100 for the adhesive 110 to adhere to the roof 100 and provide adequate adhesive strength to hold the support frame 120 and glass-glass PV module 130 in place. Contact points of the support frame experience stress due to forces applied by the weight of the support frame 120 and glass-glass PV module 130, as well as forces applied by snow, wind, seismic loads, or other sources of stress. The support frame 120 may include enough adhesive area to reduce to within an acceptable tolerance, or eliminate, risk of the applied force(s) exceeding the bond strength, so as to mitigate risk of the glass-glass PV module 130 and/or support frame 120 separating from the roof 100.

As such, in some embodiments, the support frame 120 may be designed to have a number of contact points and/or an amount of contact surface area between the support frame 120 and the roof 100 so as to account for the anticipated loads, such as loads that will be applied to the support frame 120 through the glass-glass PV module(s) 130. In some cases, the number of contact points and/or contact surface area for the support frame 120 may be chosen based on the known strength of the adhesive. The stress on the adhesive is equal to the applied load divided by the area of contact of the adhesive. As such, by choosing the adhesive surface area together with the adhesive to be used (and thus the known adhesive strength) in view of the anticipated loads, a reliable mechanism for attaching the support frame 120 and PV module(s) 130 may be devised, so as to mitigate or eliminate risk of separation from the roof 100 and/or risk of shift from creep of the support frame 120 and PV module(s) 130 from negatively impacting any components or interconnections of components.

In some embodiments, a noncontact method of adding heat to the adhesive during the application of the adhesive to the roof may be used. Applying heat during application may cause the adhesive to more rapidly bond to the roof. It may also increase wetting between the adhesive and the roof, allowing the adhesive to better flow through the granules of the shingle. This may allow the adhesive to adhere to the asphalt beneath the granules, as well as provide some mechanical locking with the granules. If the adhesive does not flow around irregularities and the surface granularity of the roof, the adhesive may only adhere to the granules and the outer surface of the roof. As these granules are often only loosely adhered to the asphalt roof, they can be easily pulled from the surface and thus adequate adhesion may not be provided.

In some embodiments the noncontact method of adding heat to the adhesive may comprise bringing an inductive coil in proximity of the support frame. An alternating current may be run through the inductive coil, creating a time-varying magnetic field around the coil. In embodiments in which the support frame is a metal support frame or an overmolded metal support frame, the varying magnetic field may induce eddy currents through the metal support frame or overmolded metal support frame. The induced current in the support frame may cause the support frame to heat up, and subsequently heat up the adhesive. In doing so, the noncontact method of adding heat may increase the strength of the adhesive bond to the roof.

In the illustrative system shown in FIG. 1, there is only one PV module 130 installed on the roof 100. However, it should be appreciated that there may be multiple glass-glass PV modules 130 installed on the roof 100. The multiple glass-glass PV modules 130 may be installed in an array (e.g., 2×4 array, 1×5 array, or any other suitable array), however, other arrangements of the glass-glass PV modules 130 are possible.

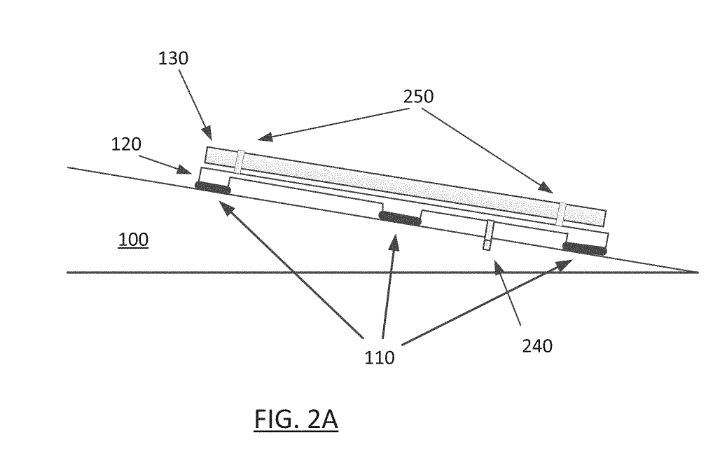

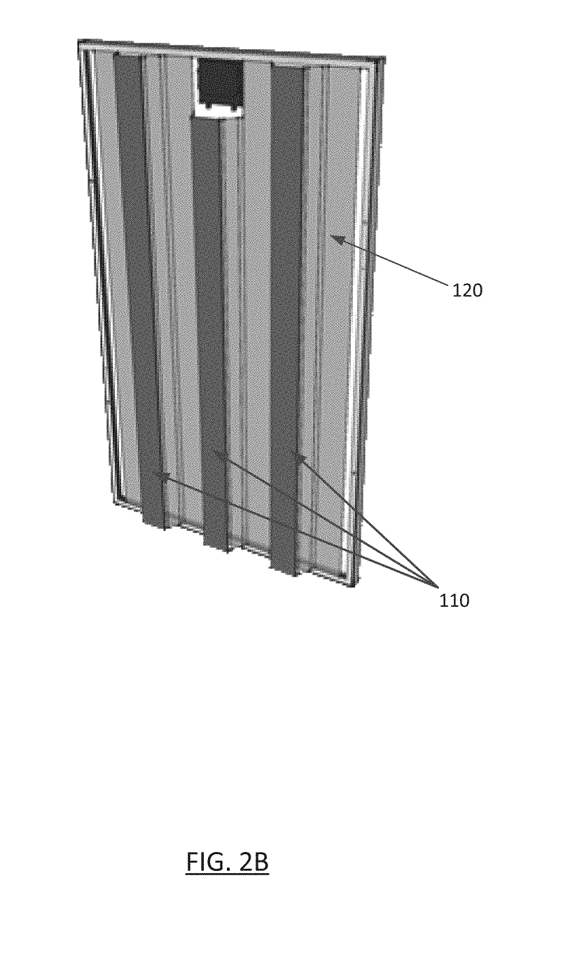

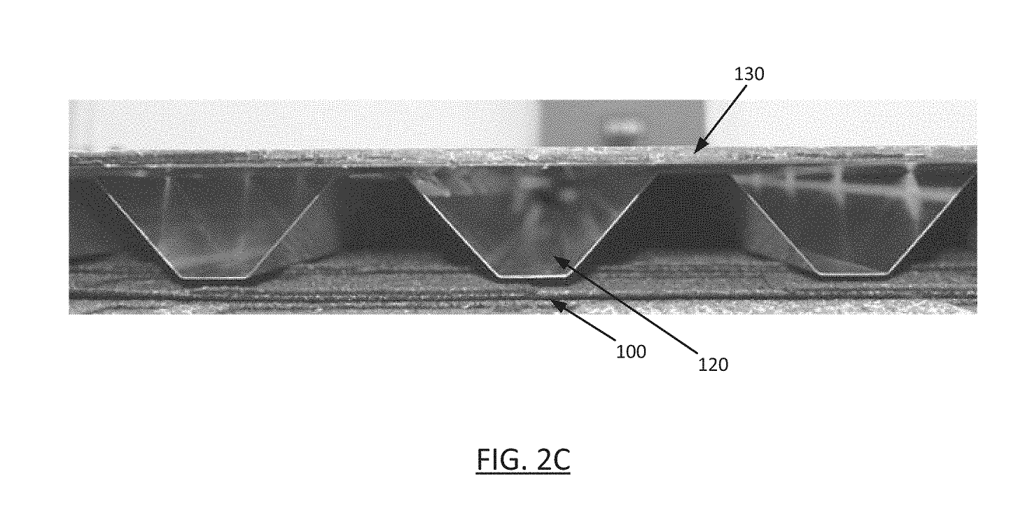

FIG. 2A shows a cross-sectional view of some embodiments of the system illustrated in FIG. 1. As should be appreciated from the discussion of FIG. 1, and as shown more clearly in FIG. 2A, in some embodiments the support frame 120 may be designed such that only some sections of the support frame 120 are attached to the roof 100 with adhesive 110. This is also shown in FIG. 2B, where the adhesive 110 is applied to only some areas of support frame 120. The support frame 120 may provide a space between the roof 100 and the support frame 120 and PV module 130. As discussed, this may provide ventilation for the PV module 130, preventing degradation of module performance due to increased temperature. The space may also provide room for electrical cables that may interconnect PV modules 130 and/or convey power generated by the PV modules 130 away from the system, such as to a central inverter of the premises of the roof 100, to an electrical grid, or other destination.

In some embodiments, the support frame 120 may be shaped as a corrugated metal plate, to provide the ventilation and space for cabling as well as provide contact area for the adhesive 110. Such a corrugated structure is illustrated in both FIGS. 2B and 2C. As discussed above, in other embodiments the support frame 120 may be a skeletal metal structure, such as a scaffold. It should be appreciated, however, that embodiments are not limited to any particular shape for the support frame 120.

While embodiments are not limited to using any particular material for the support frame 120, it may be advantageous in some embodiments for the support frame 120 to be made of non-conductive materials such as a plastic. Since glass-glass modules do not require grounding, a non-conductive support frame would ensure that the entire array need not be grounded.

In some embodiments, the apparatus may include an anchor 240 that provides supplemental support in attaching the support frame 120 to the roof 100. As discussed above, in some cases the system may suffer from creep, such as due to the weight of the system, when subjected to heavy load, when the system is disposed on a steeply-sloped roof, when the system and its adhesives are exposed to high temperature, or in other cases. The anchor 240 may aid in reducing or eliminating the chances of creep occurring.

In some embodiments, the anchor 240 may be mechanically attached to the roof 100. In such an embodiment, the anchor 240 may penetrate the roof 100 to provide additional support in holding the support frame 120 to the roof 100, such as with a bolt or screw penetrating the roof 100. As a result, installation of the anchor 240 may require installation by a qualified roofer to ensure that the anchor 240 is properly flashed.

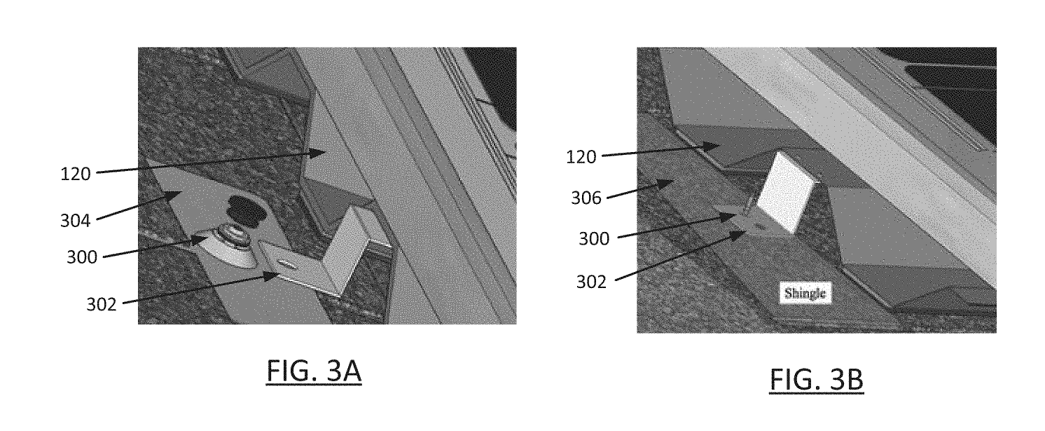

FIGS. 3A and 3B illustrate examples of mechanical anchors that penetrate the roof. In the case of FIG. 3A, an S-shape “tongue” extension 302 may protrude from the support frame 120 and be mechanically fastened to the support frame 120. The extension 302 may contact the roof 100 at the location of a flashing 304. A mechanical fastener 300, such as one or more bolts (which may include a washer, nut, or other known elements of a mechanical fastener), may connect the extension 302 and the flashing 304 to the roof 100. In the example of FIG. 3B, an extension 302 is also connected to the roof 100 via a mechanical fastener 300, which may be one or more screws. The example of FIG. 3B may not include a flashing 304, however. Instead, the example of FIG. 3B may be used in the case of a shingled roof 100, and at the point of contact with the roof 100 the extension 302 may be disposed under the tab of one of the shingles, such that the shingle sits on top of part of the extension 302.

It may be advantageous in some embodiments to eliminate mechanical anchors altogether, to avoid penetrating the roof. Accordingly, in some embodiments, the anchor 240 may be attached to the roof 100 with an adhesive. The adhesive used for the anchor 240 may, in some cases, have a higher adhesive strength and be able to withstand greater stresses than the adhesive 110. In some embodiments, the adhesive of the anchor 240 may be a temperature-resistant adhesive as the risk of creep may increase with higher temperatures. In environments where high temperatures are expected, and thus a high risk of creep is projected, an adhesive with a higher softening temperature may be advantageous in reducing or eliminating the risk of the support frame 120 and PV module 130 from shifting from their initial positions.

In some embodiments, the anchor 240 may be located on the outside of the footprint of the support frame 120 on the roof 100. In other embodiments, the anchor 240 may not be visible from outside of the system, and may be located on the underside of the support frame 120 or between the roof 100 and the PV modules 130.

The examples FIGS. 2A and 3A-3B illustrate only one anchor 240. It should be appreciated, however, that there may be multiple anchors 240 attaching the support frame 120 to the roof 100. In an embodiment in which there are multiple anchors 240, the anchors 240 may be arranged such that there is one on each side of the support frame 120, one per PV module 130, or another arrangement of anchors 240. In some cases in which there are multiple anchors, all of the anchors may be mechanical anchors or all of the anchors may be adhesive anchors, or the multiple anchors may include both mechanical anchors and adhesive anchors. For example, in some embodiments, there may be only a single mechanical anchor and one or more adhesive anchors.

FIG. 2A also illustrates that in some embodiments, the system may include fasteners 250 to couple the PV module(s) 130 to the support frame 120. In some cases, the fasteners 250 may allow for the PV module 130 to be easily attached to and detached from the support frame 120. For example, PV modules 130 may occasionally become damaged or may break altogether, and require repair or replacement. Fasteners 250 that allow a user to easily detach the PV module 130 from the support frame 120 may be advantageous in some embodiments.

In some embodiments, clamps may be used as such removable fasteners 250 to allow a user to detach the PV module 130 from the support frame 120. In some such embodiments, the clamps 250 may be arranged to allow the clamps to be disengaged from a particular PV module 130 and for the PV module 130 to be removed from the support frame 120, without having to remove adjacent modules from all sides of the module 130. For example, there may be only one clamp 250 that attaches each PV module 130 to the support frame 120. In this case, the user may only need to interact with one clamp, which may be on one side of the module 130, to detach the PV module 130 from the support frame 120. In another embodiment, there may be two clamps 250 located on opposite sides of the support frame 120, making it so that the user may need to interact two sides of the module 130 to detach it from the support frame 120, or another suitable number of clamps.

In an embodiment where multiple glass-glass PV modules 130 are installed in an array, the clamps 250 may be designed to allow the user to detach a single PV module 130 without having to detach adjacent modules in the array. This may allow for much easier module repair or replacement.

In some embodiments, the clamps 250 may be located outside of the footprint of a PV module 130 that is held by the clamps 250, and/or outside the footprint of the support frame 120. In other embodiments, the clamps 250 may not be visible from looking down from a top of the system, such as by being disposed under a PV module 130 to clamp the PV module 130 to the support frame 120 from the underside of the PV module 130.

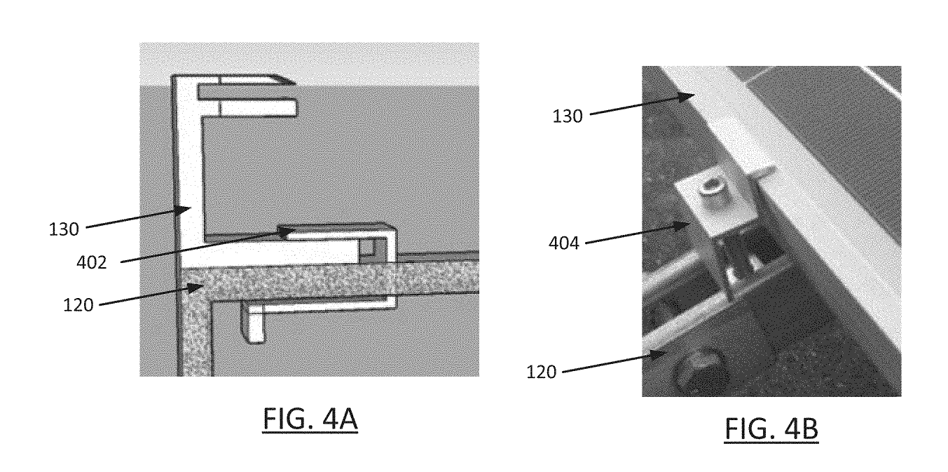

FIGS. 4A and 4B illustrate examples of clamps that may be used in some embodiments. In the example of FIG. 4A, a clamp 402 is disposed under a PV module 130 and is attached to a frame of the PV module 130. The clamp 402 of FIG. 4A may be used with glass-glass PV modules that include a frame. The clamp 402 may be engaged by sliding it so that its opening encloses the bottom lip of the frame of the PV module 130 and a section of the support frame 120. The clamp 402 may be attached to the support frame 120 in any suitable manner.

FIG. 4B illustrates a second example of a clamp, in the form of an S-shaped clamp 404 that is attached to the support frame 120 and screwed down onto the PV module 130, to hold the PV module 130 in place with a downward pressure. The screw of the clamp 404 may be attached to the support frame 120 at a fixed location, such that tightening the screw brings the clamp 404 toward the support frame 120.

FIG. 2A illustrates two clamps 250 attaching the PV module 130 to the support frame 120. It should be appreciated that there may be just a single clamp 250, or multiple clamps 250 attaching the PV module 130 to the support frame 120. In an embodiment in which there are multiple clamps 250, the clamps 250 may be arranged such that there is one on each side of the support frame 120. However, other arrangements of the clamps 250 are possible.

In embodiments in which the module 130 is a glass-glass PV module, it may be useful to use T-slots attached to the underside of the module to attach the module 130 to the support frame 120. It should be appreciated that embodiments are not limited to using any particular type of clamp or mechanical interface to attach the module 130 to the support frame 120, and those skilled in the art may select the mechanical interface to provide the functionality described herein.

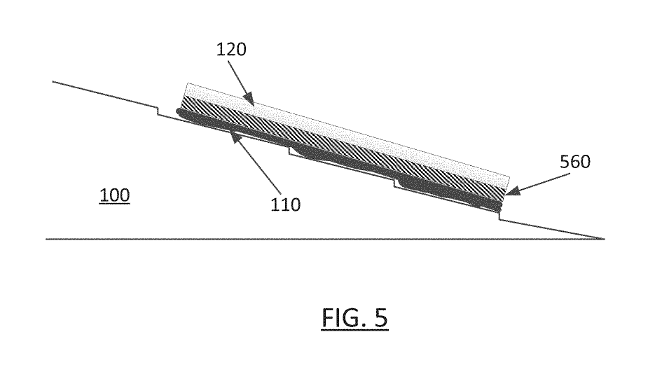

FIG. 5 shows a closer cross-sectional view of another embodiment of the system, and in particular includes an example that may be used with some steep sloped roofs 100. As discussed above, in some cases steep roofs may have an uneven surface, such as by being shingled. The bottom surface of the support frame 120 that contacts the roof 100 may be flat and rigid, however. When the flat and rigid support frame 120 contacts such an uneven surface of a shingled steep slope roof, gaps between the support frame 120 and the roof limit the contact area between the support frame 120 and the roof 100, and thus can reduce the area at which the adhesive 110 can adhere. As discussed above, a reduced contact area can lead to reduced ability of the adhesive 110 to withstand stresses, and risk separation of the support frame 120 and/or PV module(s) 130 from the roof and/or creep.

In some embodiments, a malleable material 560 (e.g., a soft foam) may be attached to the bottom surface of the support frame 120, between the support frame 120 and the adhesive 110. The adhesive 110 may be disposed between the malleable material 560 and the roof 100, such as by being applied to the malleable material 560 and contacting and adhering to the roof 100. The malleable material 560 may be able to better conform to the unevenness of the roof 100 as compared to the support frame 120, and may increase the amount of surface area of the support frame 120 and adhesive 110 that is in contact with the roof 100. In increasing the amount of surface area of adhesive 110, the malleable material 560 may increase the amount of load that the system can tolerate by decreasing the stress experienced by the adhesive, and thereby reduce the risk of separation or creep.

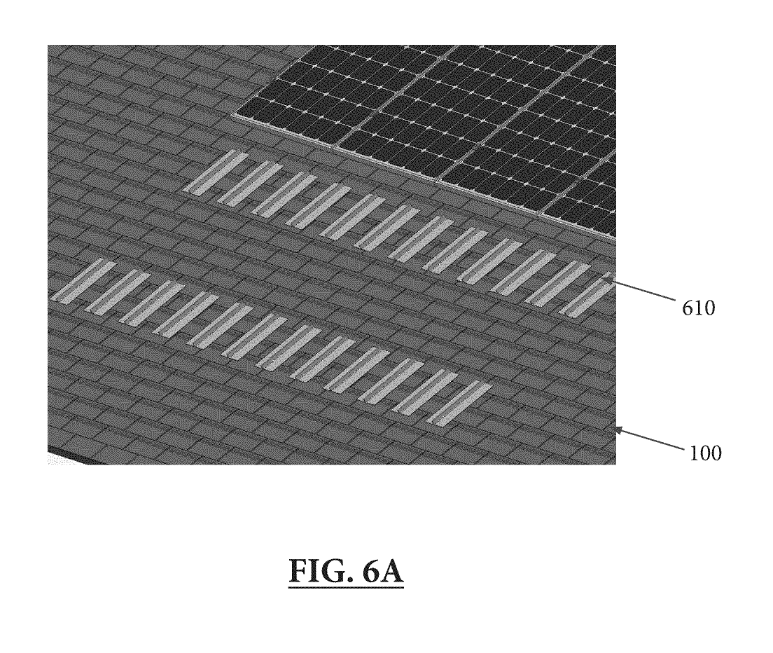

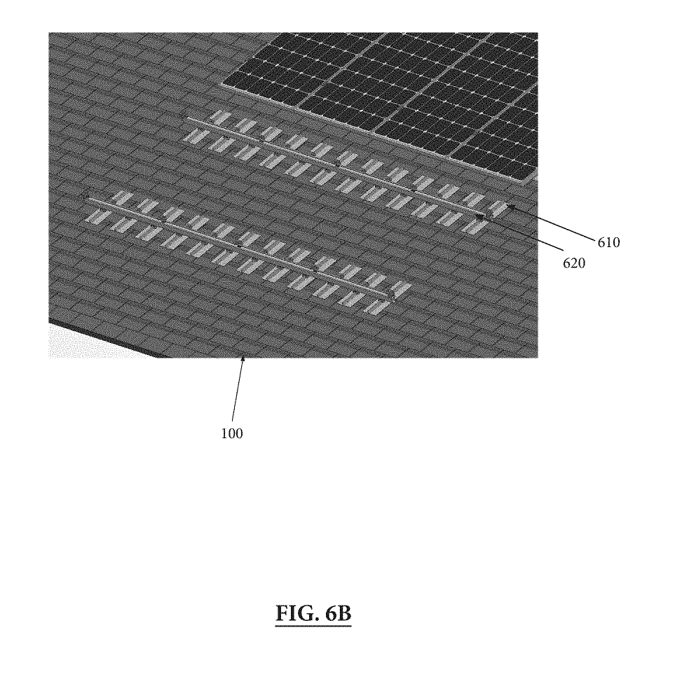

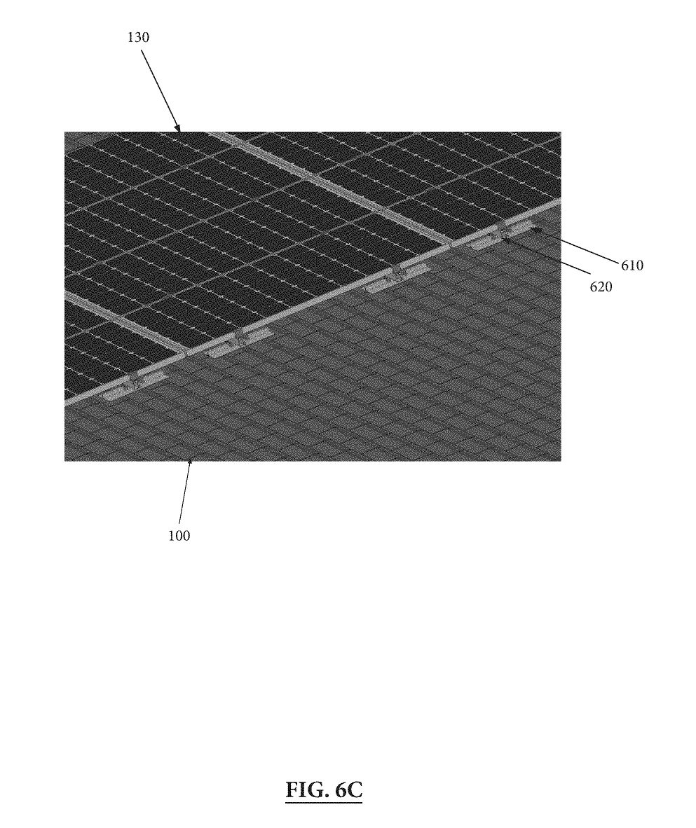

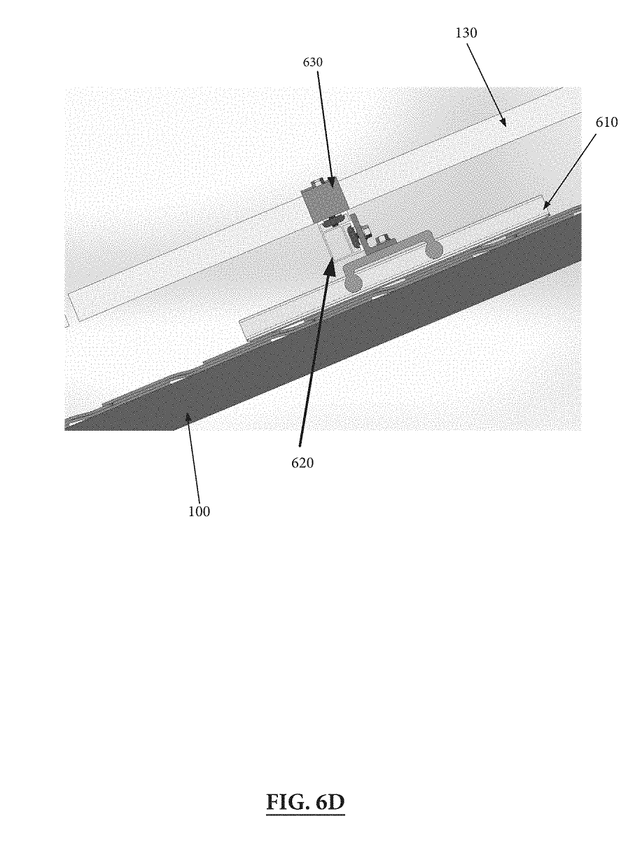

Some embodiments may include pads on which the adhesive 100 may be coated. The pads may be large enough and there may be enough pads to provide enough adhesive surface area such to withstand anticipated loads. FIG. 6A shows an embodiment in which pads 610 are coated with adhesive and applied to a roof. The pads 610 may be configured such that the support frame 120 may be able to attach to the pads 610.

In some embodiments, the pads 610 may be small enough such that they are able to avoid the unevenness of the roof on the length-scale of the shingles. In this embodiment, the pads 610 may have a length, in a direction parallel to the roof, that is shorter than the exposed portion of the shingle tab. In doing so, the fraction of adhesive in direct contact with the shingle is greater than if the pad 610 spanned an overlap in the direction parallel to the roof. This arrangement may make more efficient use of the adhesive.

FIG. 6B shows an embodiment in which rails 620 are attached to the pads 610. In such embodiments, the rails 620 may be attached to the pads 610 in order to hold a PV module 130 to the roof 100. FIG. 6C shows a PV module 130 attached to the rails 620, which are attached to the pads 610, which are adhered to the roof 100. It should be appreciated that the rails 620 may be attached to the pads 610, and the PV module 130 may be attached to the rails 620, in any appropriate way. For example, they may be attached using clamps as previously discussed, or they may be attached using T-slots. FIG. 6D shows a close-up view of a PV module 130 attached to a rail 620, attached to a pad 610, attached to the roof 100. The PV module 130 may be attached to the rail 620 with an L-shaped clamp, or any other type of clamp. The PV module 130 may also be attached to the rail 620 with an angled bracket. The rail 620 may also include another clamp 630 to hold the PV module 130 in place.

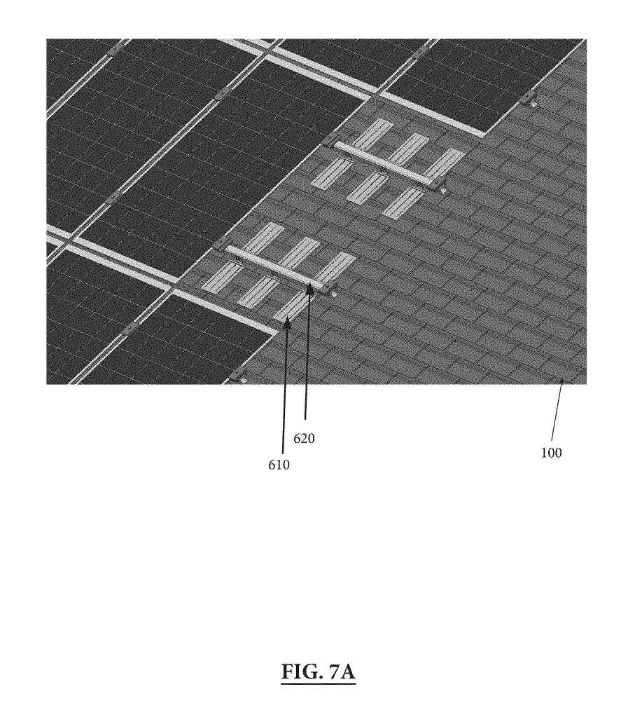

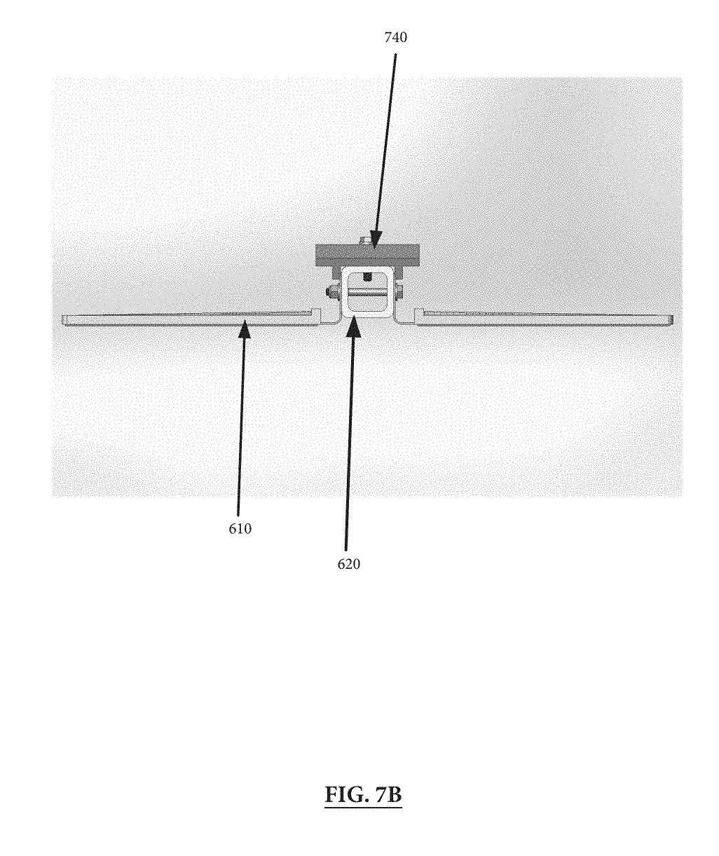

In another embodiment, the rails 620 may be attached between pads 610. The rails 620 may not be disposed directly above the pads 610, but are attached between two adjacent rows of pads 610. FIG. 7A shows a top view of such an embodiment. FIG. 7B shows a side view of such an embodiment. In some embodiments, the rail 620 may be attached to two adjacent rows of pads 610 with an angled bracket. The rail 620 may include a clamp 740 that may allow a PV module 130 to attach to the rail 620. In this embodiment, the rails 620 may be designed to have a lower profile than a design in which the rails 620 are attached directly above pads 610. The rails 620 may be in contact with the roof 100, or may be closer to the roof 100 than a top surface of the pad 610.

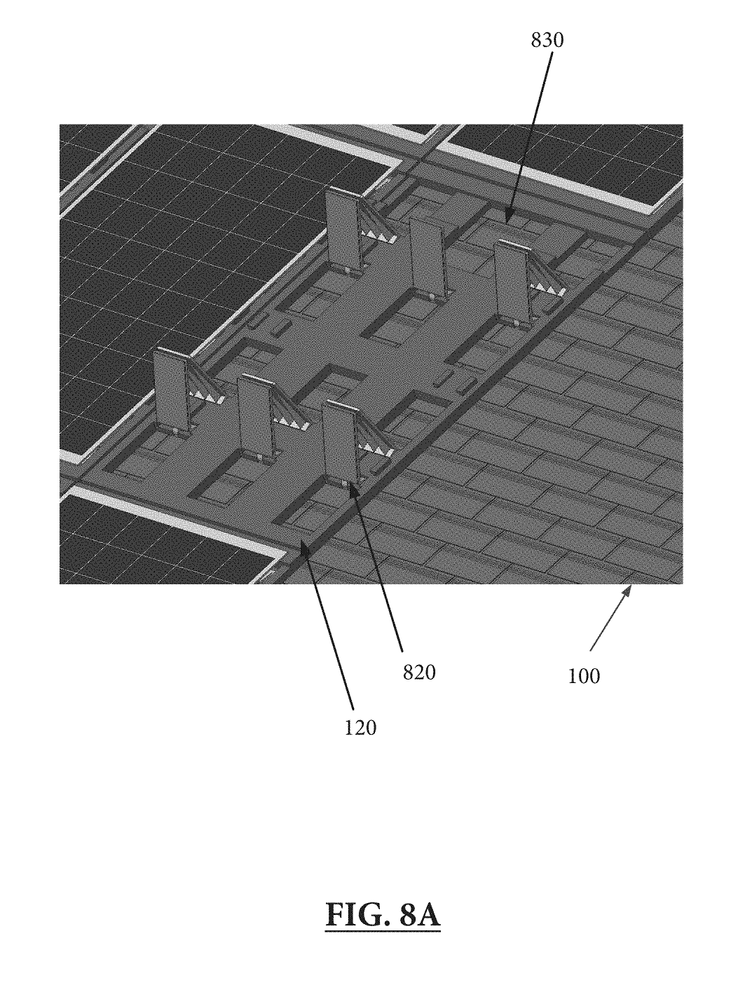

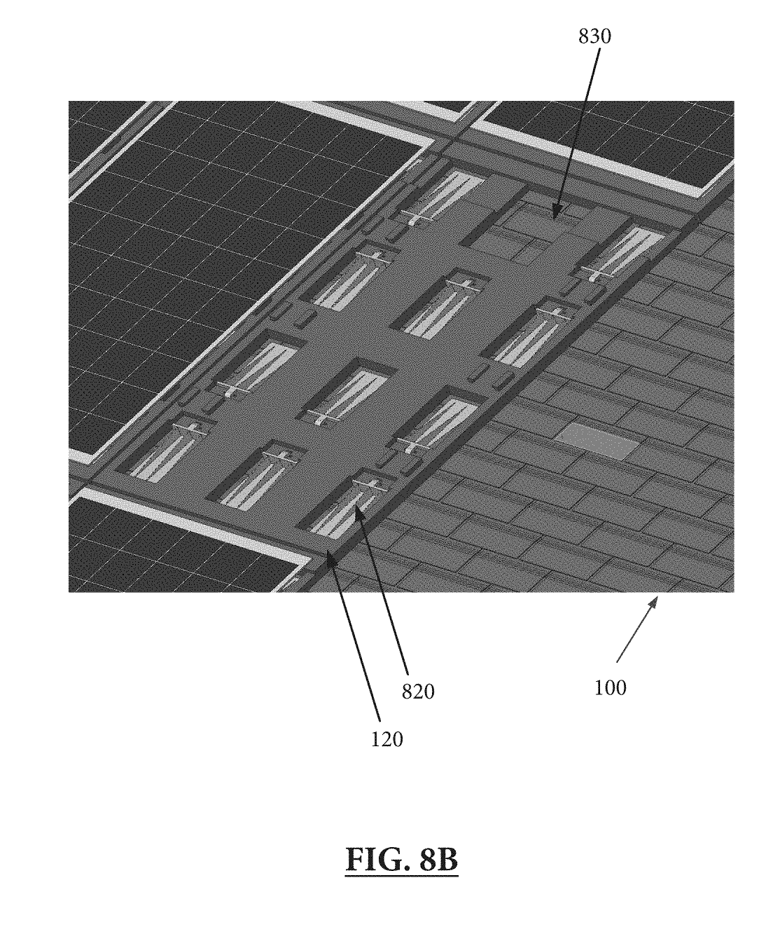

In some embodiments, such as with a glass-glass PV module 130, the support frame 120 may have hinged pads on which the adhesive 110 may be applied. The hinged pads may be hinged such that the adhesive may not be in contact with the roof 100 in a first position and may be in contact with the roof 100 in a second position. FIG. 8A shows an embodiment in which the hinged pads 820 are in the first position. FIG. 8B shows an embodiment in which the hinged pads 820 are in the second position. This may allow for the support frame 120 to slide freely on the roof 100 and allow for easier alignment while the hinged pads are in the raised, first position and before the adhesive contacts the roof. Once the support frame 120 is correctly aligned on the roof 100, the hinged pads may each be placed in the second position so that the adhesive 110 may adhere to the roof 100.

In such an embodiment, the support frame 120 may also define a space 830 in which there is no hinged pad. The space 830 may provide room for the junction box of the PV module to be located.

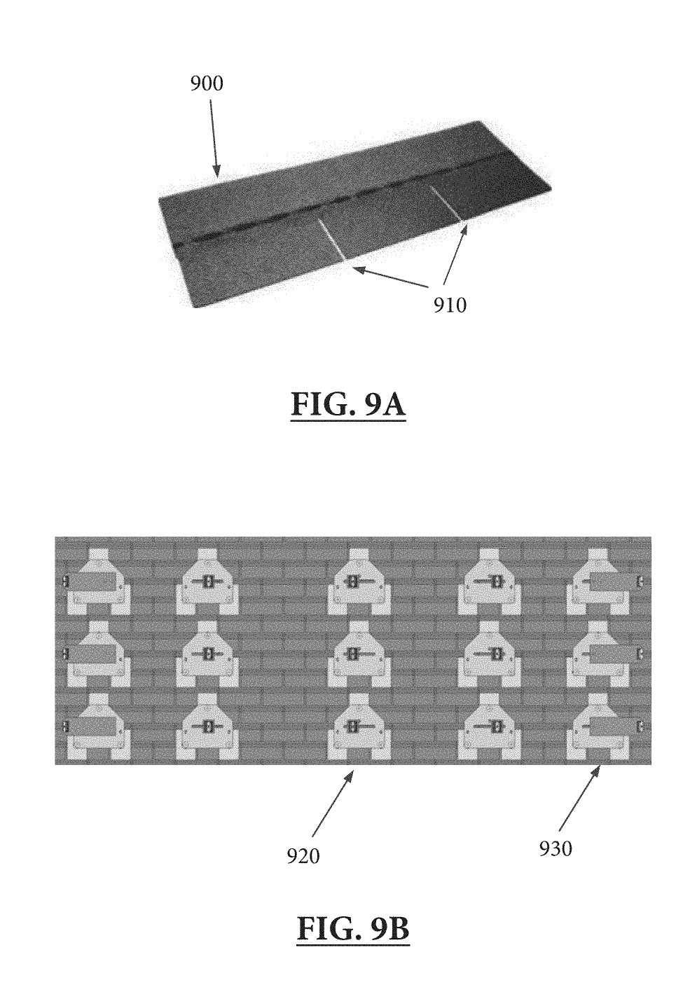

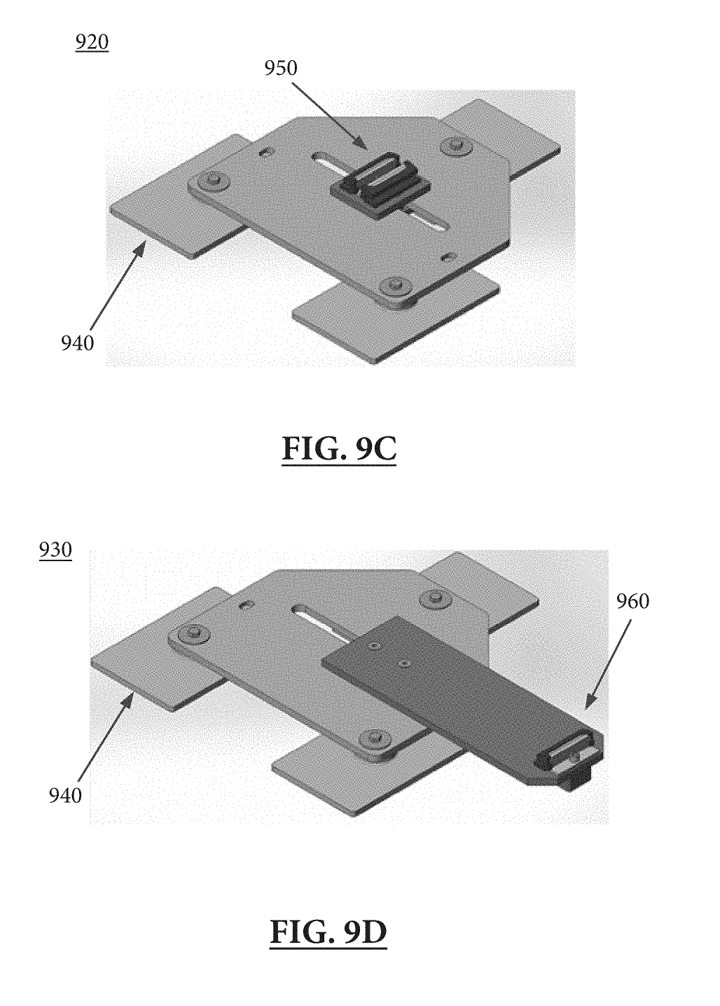

FIGS. 9A-D show an embodiment in which a PV module may be attached to a roof using an arrangement of three mounting pads, which is referred to herein as a “triad” design. Some roofs may be surfaced with shingles having notches separating different tabs of the shingle. An example of a “three-tab” shingle 900 is shown in FIG. 9A. The shingle 900 may include the notches 910, which may be introduced for aesthetic reasons. If the notches 910 of the shingle 900 were blocked, such as with an adhesive pad when a PV array is attached to the roof, this may cause water to undesirably build up in the area of the shingle 900 and potentially pass under the shingle 900 and/or under the roof. Similarly, if an adhesive pad were placed adjacent to the notch 910 and below the notch 910 along a surface of the roof, water or ice may back up into the notch 910, and cause similar undesirable water ingress.

To reduce or prevent such undesirable water ingress, the “triad” mount design may be used in some embodiments. FIG. 9B illustrates an arrangement of triad PV mounts, in an array of 3×5 triad mounts. Pairs of columns of mounts may be used to support a PV module, such that the five columns of FIG. 9B may support four PV modules. The arrangement shown in FIG. 9B includes nine central triad PV mounts 920 and six end triad PV mounts 930. It should be appreciated that the arrangement shown in FIG. 9B is for illustrative purposes only and that other arrangements are possible. The structure of each triad mount of FIG. 9B may be better understood from FIGS. 9C and 9D.

FIG. 9C shows a closer view of a central triad PV mount 920. The central triad PV mount 920 may include three adhesive pads 940. The adhesive pads 940 may be of smaller size than the adhesive pads described in other embodiments. For example, the adhesive pads 940 may be sized such that they have a width less than or equal to half the width of a tab of shingle 900. The adhesive pads 940 may also have a length that is less than a length of a shingle 900. With such dimensions, as may be appreciated from FIG. 9B, when an adhesive pad is applied to a roof with an edge of the adhesive pad 940 approximately flush with an edge of one of the shingles 900, the adhesive pad 940 may overlap and contact a surface of two shingles 900 but not overlap any of the notches for those two shingles 900. In doing so, none of the notches may be blocked, and water ingress may be reduced or prevented. A mount 930 of the triad PV mount 920 may also include an adjustable pair of fasteners 950 (e.g., clamps). The adjustable pair of fasteners 950 may be configured to attach to two glass-glass PV modules, and each may be configured to slide left-to-right on the mount 920 to accommodate attaching to a PV module at different positions, to account for potential different positions of a PV module.

FIG. 9D shows a closer view of an end triad PV mount 930. Similar to the central triad PV mount 920 shown in FIG. 9C, the end triad PV mount 930 may include three adhesive pads 940. The adhesive pads 940 may be of smaller size than the adhesive pads described in other embodiments. For example, the adhesive pads 940 may be sized such that they have a width less than or equal to half the width of a tab of shingle 900. The adhesive pads 940 may also have a length that is less than a length of a shingle 900. With such dimensions, as may be appreciated from FIG. 9B, when an adhesive pad is applied to a roof with an edge of the adhesive pad 940 approximately flush with an edge of one of the shingles 900, the adhesive pad 940 may overlap and contact a surface of two shingles 900 but not overlap any of the notches for those two shingles 900. In doing so, none of the notches may be blocked, and the risk of water ingress may be reduced or prevented. The end triad PV mount 930 may also include an arm 960. The arm 960 may be configured to attach to a glass-glass PV module, and may be configured to slide left-to-right on the mount 930. The arm 960 includes, at a distal end of the arm 960, a fastener (e.g., clamp) to attach to the PV module. By including the clamp at the distal end of the arm 960, an attachment point between the mount 930 and a PV module may be located some distance from the mount 930, such that the PV module overlaps the mount 930 and the mount 930 may be largely hidden from view.

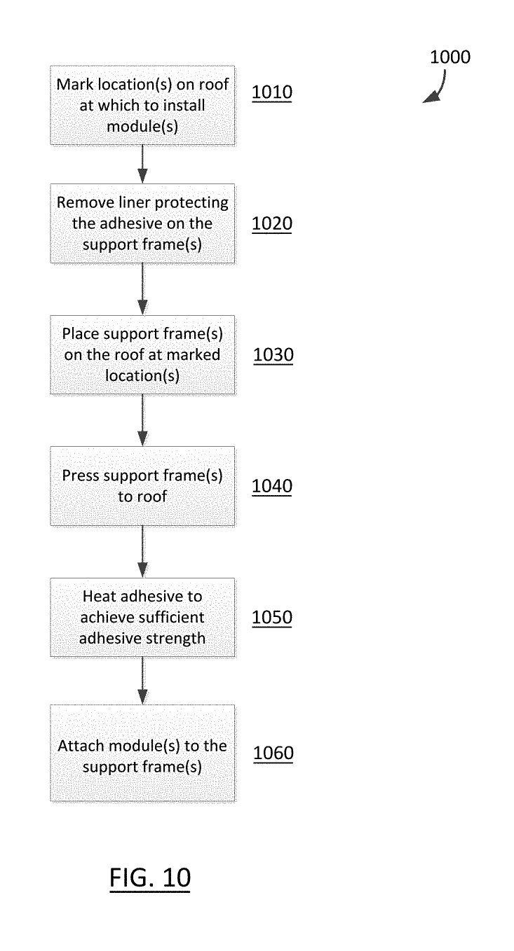

FIG. 10 illustrates a flowchart of a process 1000 for installing a PV module on a steep-slope roof of a premises, according to some embodiments. The process 1000 begins at block 1010, in which an installer marks the location(s) on the roof at which glass-glass PV module(s) are to be installed. The process 1000 continues in block 1020 in which the installer removes a liner protecting an exposed side of the adhesive that is on the support frame(s) (and/or on a malleable material of the support frame), where the exposed side is the side that is to contact the roof. The installer may then in block 1030 place the support frame(s) on the roof at the marked location(s), such that the adhesive contacts and begins to adhere to the roof. At block 1040, the installer may press the support frame(s) against the roof more forcefully, to achieve desired contact and sufficient adhesive strength. In some cases, following contact of the adhesive to the roof, an installer may wait for a time, until the adhesive has sufficiently bonded to the roof for more weight to be applied to the adhesive. The installer may also, at block 1050, heat the adhesive in order to more rapidly increase bond strength. The installer may then at block 1060 attach the PV module(s) to the support frame(s).

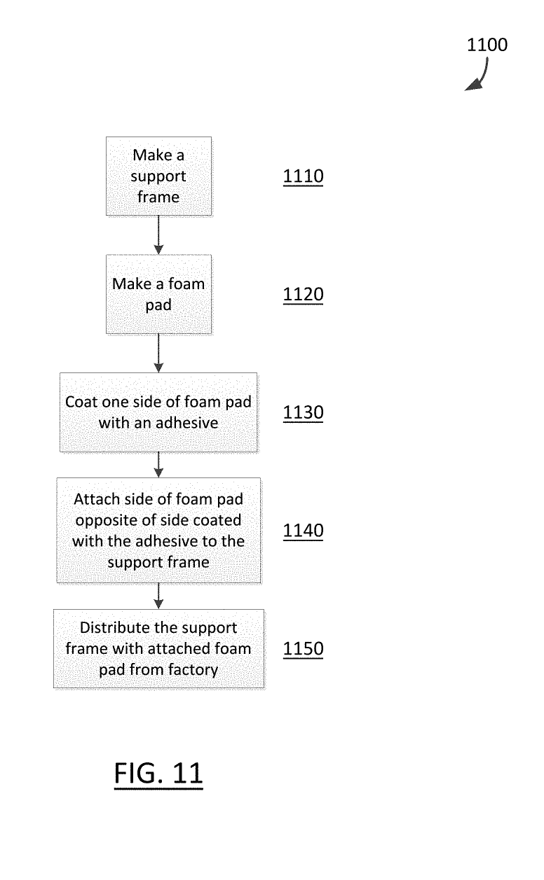

FIG. 11 illustrates a flowchart of an example of a process for manufacturing a PV module support system of the type described herein. The process 1100 begins in block 1110, in which a manufacturer makes or obtains a support frame. As described above, embodiments are not limited to a support frame of a particular shape or material. Examples of support frames include metal corrugated shapes and metal scaffold shapes. At block 1120, the manufacturer creates or obtains one or more pads of malleable material. As discussed above, an example of such a pad is a foam pad. The manufacturer in block 1130 coats one side of the pad with an adhesive and, in block 1140, attaches the side of the pad opposite the side coated with the adhesive to the support frame. The process may then include a step 1150 of distribute the support frame with the attached foam pad.

The process shown in FIG. 11 may also, before distributing from the factory, include a making or obtaining a PV module. The process 1100 may in such cases also include an act of coupling the PV module to the support frame.

Various aspects of the present invention may be used alone, in combination, or in a variety of arrangements not specifically discussed in the embodiments described in the foregoing, and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Further, some actions are described as taken by a “user.” It should be appreciated that a “user” need not be a single individual, and that in some embodiments, actions attributable to a “user” may be performed by a team of individuals and/or an individual in combination with computer-assisted tools or other mechanisms.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An apparatus for attaching at least one glass-glass photovoltaic module to a sloped roof, the apparatus comprising:
a support frame comprising:
a mechanical interface configured to hold the at least one glass-glass photovoltaic module; and
at least one surface, disposed opposite the mechanical interface, coated with an adhesive to couple the apparatus to the sloped roof.

2. The apparatus according to claim 1, wherein the adhesive is a pressure-sensitive adhesive.

3. The apparatus according to claim 1, wherein the mechanical interface is configured to hold the glass photovoltaic module a distance from the roof, the distance being between 1 inch and 7.5 inches.

4. The apparatus according to claim 1, wherein the support frame includes at least one anchor configured to attach directly to the sloped roof.

5. The apparatus according to claim 4, wherein the at least one anchor is configured to attach directly to the sloped roof with a temperature-resistant adhesive.

6. The apparatus according to claim 1, wherein at least an outer layer of the support frame is nonmetal.

7. The apparatus according to claim 1, wherein the support frame further comprises a malleable material on the at least one surface disposed opposite the mechanical interface, wherein the malleable material is coated with the adhesive to couple the apparatus to the sloped roof.

8. The apparatus according to claim 1, wherein the mechanical interface comprises a plurality of reversible clamps configured to hold the glass-glass photovoltaic module in place and allow for the removal of the glass-glass photovoltaic module from the support frame.

9. The apparatus according to claim 8, wherein the plurality of reversible clamps includes a first clamp and a second clamp, wherein the second clamp is disposed on a side of the mechanical interface opposite the first clamp.

10. The apparatus according to claim 1, wherein the at least one surface disposed opposite the mechanical interface comprises at least one adhesive pad.

11. The apparatus according to claim 10, wherein the at least one adhesive pad is smaller than the length of a shingle of the roof.

12. The apparatus according to claim 10, wherein the support frame further comprises a rail, wherein the rail is configured to attach to the adhesive pads and to the mechanical interface.

13. The apparatus according to claim 12, wherein the mechanical interface comprises a plurality of clamps, and the rail is configured to attach to the plurality of clamps in order to attach a plurality of glass-glass photovoltaic modules to the sloped roof.

14. The apparatus according to claim 10, wherein the at least one adhesive pad includes a hinge, wherein the hinge is configured to allow the at least one adhesive pad to not contact the sloped roof in a first position, and contact the sloped roof in a second position.

15. The apparatus according to claim 10, wherein the at least one surface disposed opposite the mechanical interface comprises a plurality of adhesive pads, wherein the plurality of adhesive pads are configured to attach to the sloped roof such that none of the plurality of adhesive pads are located below a notch of a shingle on the sloped roof.

16. The apparatus according to claim 8, wherein the plurality of reversible clamps are configured to slide.

17. A method for installing at least one glass-glass photovoltaic module to a sloped roof, the method comprising:
marking at least one location on the sloped roof at which to install the at least one glass-glass photovoltaic module;
removing a liner protecting an adhesive coated on at least one support frame, the at least one support frame being configured to hold the at least one glass-glass photovoltaic module in place;
placing the at least one support frame on the sloped roof at the at least one location;
pressing the at least one support frame to achieve sufficient adhesive strength; and
attaching the at least one glass-glass photovoltaic module to the at least one support frame.

18. A method for manufacturing an apparatus for attaching a glass-glass photovoltaic module to a sloped roof, the method comprising:
making a support frame;
making a foam pad;
coating one side of the foam pad with an adhesive;
attaching a side of the foam pad opposite the side coated with the adhesive to the support frame; and
distributing the support frame with the attached foam pad from a factory.

19. The method according to claim 18, wherein the method further comprises:
making a glass-glass photovoltaic module; and
coupling the glass-glass photovoltaic module to the support frame.
